(19) United States
(12) Patent Application Publication
(10) Pub. No.: US 2026/0066220 A1
(43) Pub. Date: Mar. 5, 2026

(54) SLIP EVALUATION METHOD AND CHARGED PARTICLE BEAM WRITING METHOD

(71) Applicant: NuFlare Technology, Inc., Yokohama-shi (JP)

(72) Inventors: Taichi ISHIGURO, Yokohama-shi (JP); Ryo SUDO, Yokohama-shi (JP)

(73) Assignee: NuFlare Technology, Inc., Yokohama-shi (JP)

(21) Appl. No.: 19/270,840

(22) Filed: Jul. 16, 2025

(30) Foreign Application Priority Data
Sep. 2, 2024 (JP) 2024-150870

(51) Int. Cl. H01J 37/304; H01J 37/20; H01J 37/317

(52) U.S. Cl. CPC H01J 37/3045; H01J 37/20; H01J 37/3174; H01J 2237/30483

(57) ABSTRACT

In one embodiment, a slip evaluation method includes placing a calibration substrate in which at least one mark is formed on a movable stage in a charged particle beam writing apparatus, measuring a first position of the mark with the stage stopped, performing a slip trigger stage operation at an acceleration to be evaluated, measuring a second position of the mark with the stage stopped after the slip trigger stage operation is performed, and calculating an amount of slip of the calibration substrate based on the first position and the second position.

### CROSS REFERENCE TO RELATED APPLICATION

This application is based upon and claims benefit of priority from the Japanese Patent Application No. 2024-150870, filed on Sep. 2, 2024, the entire contents of which are incorporated herein by reference.

### FIELD The present invention relates to a slip evaluation method and a charged particle beam writing method.

### BACKGROUND

As LSI circuits are increasing in density, the required linewidths of circuits included in semiconductor devices become finer year by year. To form a desired circuit pattern on a semiconductor device, a method is employed in which a high-precision original pattern formed on quartz is transferred to a wafer in a reduced manner by using a reduced-projection exposure apparatus. The high-precision original pattern is written by using an electron-beam writing apparatus, in which a so-called electron-beam lithography technique is employed.

In an electron beam writing apparatus, a substrate is placed on support pins on a stage, and the substrate is irradiated with an electron beam to write a pattern while the stage is being moved. The substrate is simply placed on the support pins, and not fixed to the support pins, thus an inertia force exerted on the substrate due to acceleration or deceleration of the stage may exceed the frictional force generated between the substrate and the support pins, and the substrate may be slipped over the support pins. When the substrate is slipped over the support pins, a problem arises in that the positional accuracy of pattern writing is reduced.

### BRIEF DESCRIPTION OF THE DRAWINGS

FIG. 1 is a schematic view of an electron beam writing apparatus according to an embodiment of the present invention.

FIG. 2 is a plan view of a calibration substrate.

FIG. 3 is a cross-sectional view of the calibration substrate.

FIG. 4 is a flowchart for explaining a slip evaluation method according to the embodiment.

### DETAILED DESCRIPTION

In one embodiment, a slip evaluation method includes placing a calibration substrate in which at least one mark is formed on a movable stage in a charged particle beam writing apparatus, measuring a first position of the mark with the stage stopped, performing a slip trigger stage operation at an acceleration to be evaluated, measuring a second position of the mark with the stage stopped after the slip trigger stage operation is performed, and calculating an amount of slip of the calibration substrate based on the first position and the second position.

Hereinafter, an embodiment of the present invention will be described based on the drawings. In the present embodiment, a configuration using an electron beam as an example of a charged particle beam will be described. The charged particle beam is not limited to the electron beam. For example, the charged particle beam may be an ion beam.

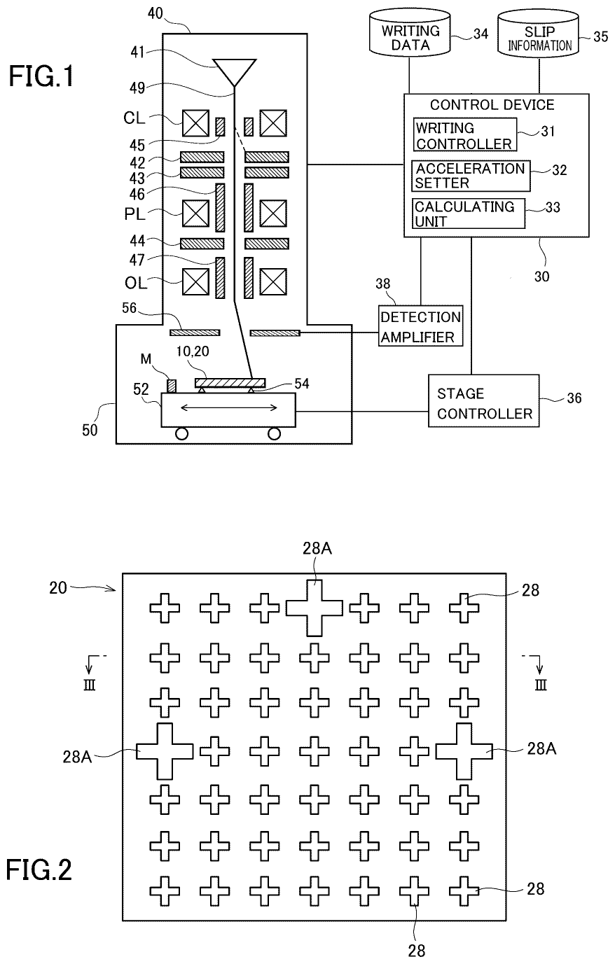

FIG. 1 is a schematic view of an electron beam writing apparatus according to an embodiment of the present invention. The electron beam writing apparatus includes an electron optical column 40, a writing chamber 50, a control device 30, storage devices 34, 35, a stage controller 36, and a detection amplifier 38. In the electron optical column 40, an electron source 41, a blanking aperture 42, a first aperture 43, a second aperture 44, a blanking deflector 45, a shaping deflector 46, an object deflector 47, an illumination lens CL, a projection lens PL, and an objective lens OL are disposed.

In the writing chamber 50, an XY stage 52 is movably disposed. On the XY stage 52, a substrate 10 as a writing target is placed at the time of writing a pattern. For example, the substrate 10 is such that a light shielding film such as a chrome film and a resist film are layered.

Multiple (for example, three) support pins 54 are provided on the XY stage 52, and the substrate 10 is placed on the support pins 54.

A mark M is set and fixed to a region on the XY stage 105, the region being different from the region where the substrate is placed. The mark M (fixed mark) is, for example, a cross mark made of metal.

In the writing chamber 50, a detector 56 is provided for detecting a reflected electron when the mark M or the later-described calibration substrate 20 is irradiated with an electron beam 49. A result of the detection by the detector 56 is transmitted to the control device 30 through the detection amplifier 38.

The electron beam 49 emitted from the electron source 41 illuminates the entire first aperture 43 having a rectangular opening by the illumination lens CL. First, the electron beam 49 is shaped into a rectangle. The electron beam having a first aperture image, which has passed through the first aperture 43, is projected on the second aperture 44 by the projection lens PL. The position of the electron beam having a first aperture image on the second aperture 44 is controlled by the shaping deflector 46, thus the beam shape and dimensions can be changed. The electron beam having a second aperture image, which has passed through the second aperture 44, is focused by the objective lens OL, and deflected by the object deflector 47, then radiated to a target position of the substrate 10 on the XY stage 52.

The electron beam 49 is deflected by the blanking deflector 45 so that in a beam-ON state, the electron beam 49 is controlled to pass through the blanking aperture 42, and in a beam-OFF state, the entire beam is blocked by the blanking aperture 42. The electron beam for one shot is formed by the beam which has passed through the blanking aperture 42 during a period since beam-ON after a beam-OFF state until beam-OFF is achieved subsequently. The irradiation amount per shot of the electron beam emitted to the resist film on the surface of the substrate 10 is adjusted by the irradiation time of each shot.

The components of the electron beam writing apparatus are controlled by the control device 30. The control device 30 has the functions of a writing controller 31, an acceleration setter 32 and a calculating unit 33. The writing controller 31 reads writing data from the storage device 34, and performs multi-stage data conversion process to generate shot data specific to the apparatus. In the shot data, the irradiation amount, irradiation position coordinates and the like of each shot are defined. The writing controller 31 controls the amount of deflection of the object deflector 47 and the amount of movement of the XY stage 52 based on the shot data to change the irradiation position of the electron beam. The writing controller 31 controls the amount of deflection of the shaping deflector 46 based on the shot data to change the beam shape and dimensions. Thus, the resist film on the substrate 10 can be irradiated with an electron beam with varying shape and dimensions.

The acceleration setter 32 sets the acceleration of the XY stage 52. The stage controller 36 controls the movement speed of the XY stage 52 so that it moves at the set acceleration.

In a writing process, an inertia force is exerted on the substrate 10 due to acceleration or deceleration of the XY stage 52, and the substrate 10 may be slipped over the support pins 54. In the present embodiment, the calibration substrate 20 is placed on the support pins 54, and the XY stage 52 is moved with multiple accelerations, then the amount of slip (the amount of positional deviation) of the calibration substrate 20 at each acceleration is evaluated, and the acceleration of the XY stage 52 not causing slip is determined.

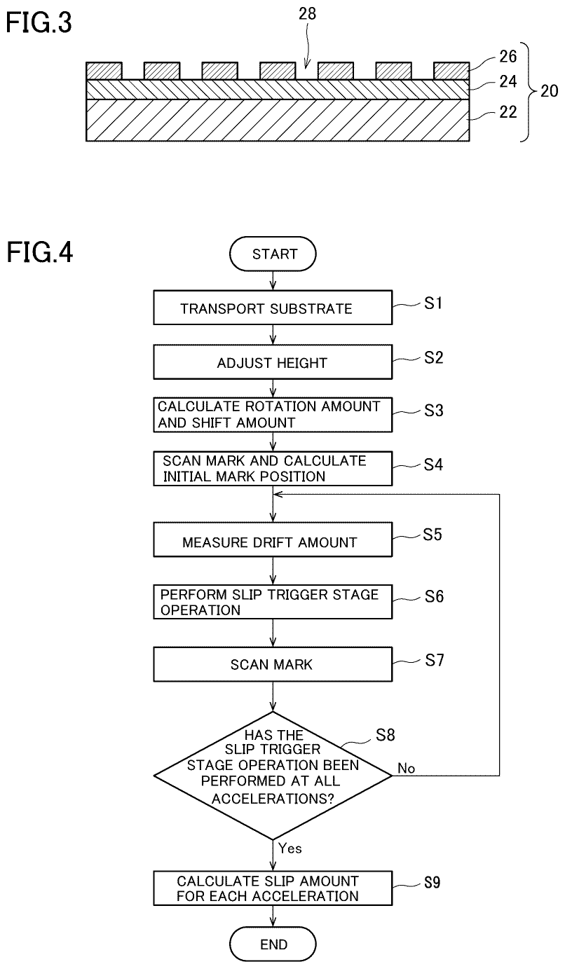

FIG. 2 is a plan view of the calibration substrate 20 used for slip evaluation, and FIG. 3 is a cross-sectional view taken along III-III line in FIG. 2. The calibration substrate 20 includes a substrate body 22, a conductive film 24 (first conductive film) and a conductive film 26 (second conductive film) which are sequentially layered. In the conductive film 26, a plurality of marks 28 having openings penetrating to the conductive film 24 are regularly disposed. It is preferable that the plurality of marks 28 be substantially uniformly disposed on the entire substrate surface to avoid uneven distribution. The bottom surface of each mark 28 serves as part of the conductive film 24, thus even if electron beams are emitted, charging by electrons can be avoided. Thus, an unexpected error due to charging by electrons does not occur. For example, the calibration substrate 20 and the ground member may be connected by bringing pins connected to the ground into contact with the conductive film 24 or the conductive film 26 from the upper surface side of the calibration substrate 20.

The mark 28 has e.g., a cross shape. As illustrated in FIG. 2, three marks located at the center left end, the center right end and the center upper end among the marks 28 formed on the calibration substrate 20 may be used as alignment marks 28A having a larger size (line width and length) than that of the other marks 28.

It is preferable that for the conductive film 26, a material with a reflectance higher than the reflectance of the conductive film 24 be used. As the material for the conductive film 26, it is possible to use tantalum (Ta), tungsten (W), platinum (Pt) or a compound thereof, and as an example, boron-doped tantalum may be used. As the material for the conductive film 24, it is possible to use chrome (Cr), titanium (Ti), vanadium (V) or a compound thereof, and as an example, chromium nitride may be used. However, the materials for the conductive film 24, 26 should be conductive films with different reflectances, and are not limited to the above-mentioned metal-containing materials.

The conductive film 24 is exposed to the bottom surface of the marks 28, and the surface of the region other than the marks 28 forms the conductive film 26 with a reflectance different from the reflectance of the conductive film 24, thus the contrast of a reflection signal detected by scanning the calibration substrate 20 with an electron beam can be increased.

It is preferable that a low thermal expansion glass be used for the substrate body 22.

Next, a slip evaluation method according to the present embodiment will be described with reference to the flowchart illustrated in FIG. 4.

First, the calibration substrate 20 is transported to the writing chamber 50 of the electron beam writing apparatus, and placed on the support pins 54 of the XY stage 52 (step S1).

Z-direction (height) position of the calibration substrate 20 is adjusted, and the electron beam is focused on the surface of the calibration substrate 20 (step S2). For example, with the XY stage 52 stopped, the electron beam is deflected by the object deflector 47 to scan the mark 28 at the center of the calibration substrate 20, and a reflected electron is detected by the detector 56. The detector 56 outputs a reflection electron signal indicating the intensity (quantity) of the detected reflected electron to the control device 30 through the detection amplifier 38. The calculating unit 33 calculates the height and width of the scan waveform from the reflected electron signal.

Mark scan, detection of a reflected electron, and calculation of the width and height of the scan waveform are performed while changing the height of the calibration substrate 20. When focus is made on the surface of the calibration substrate 20, the width of the scan waveform is minimized, and the height of the scan waveform is maximized. The height of the calibration substrate 20 is adjusted to the focus position of the electron beam based on the width and height of the calculated scan waveform.

Next, the amount of rotation and the amount of shift of the calibration substrate 20 placed on the XY stage 52 are calculated (step S3). For example, with the XY stage 52 stopped, the marks 28 of the calibration substrate 20 are scanned to detect reflected electrons. Among the marks 28, the alignment marks 28A are different in size from other marks 28, thus their scan waveforms are also different. The calculating unit 33 detects the positions of three alignment marks 28A from the scan waveforms corresponding to the alignment marks 28A, and the amount of deflection of the electron beam. The calculating unit 33 calculates the amount of rotation and the amount of shift of the calibration substrate 20 from the detected positions of the three alignment marks 28A. It is found that the marks 28 are deviated from the design coordinates by the calculated amount of rotation and amount of shift, which is taken in consideration in the subsequent position calculation of the marks 28. The number of alignment marks 28A is not limited to three. At least two alignment marks 28A are required, and the number may be more than three.

Next, with the XY stage 52 stopped, the marks 28 of the calibration substrate 20 are scanned (step S4). Reflected electrons are detected by the detector 56, and the calculating unit 33 calculates the initial positions of the plurality of marks 28 using the result of detection of the reflected electrons. For example, 3 positions at predetermined intervals in the x direction and 3 positions at predetermined intervals in the y direction are provided, thus the positions of totally 9 (=3×3) marks 28 are calculated. The mark positions can be determined from the change in the intensity of the reflected electrons, and the stage position. At this point, the positions of the marks 28 are calculated in consideration of the amount of rotation and the amount of shift of the calibration substrate 20 calculated in step S3.

Next, the amount of drift of the electron beam is measured (step S5). The XY stage 52 is moved to adjust the mark M to the central position of the objective lens OL, and the mark M is scanned with the electron beam to detect a reflected electron by the detector 56. The calculating unit 33 detects the beam irradiation position using the beam profile based on the result of detection of a reflected electron, and the stage position (the position of the mark M). The calculating unit 33 calculates, as the amount of drift, the amount of deviation from the reference position of the detected beam irradiation position.

The stage controller 36 controls the XY stage 52, and performs a slip trigger stage operation (a slip-prompted stage motion) with the acceleration set by the acceleration setter 32 (step S6). The slip trigger stage operation is a stage motion that can cause slip of the substrate, for example, a stage reciprocating motion including movement in +X direction and movement to −X direction.

After the slip trigger stage operation is performed, with the XY stage 52 stopped, the marks 28 of the calibration substrate 20 are scanned (step S7). As in the process of calculating the initial mark positions, reflected electrons are detected by the detector 56, and the calculating unit 33 calculates the positions of the plurality of marks 28 using the result of detection of reflected electrons. At this point, the positions of the marks 28 are calculated in consideration of the amount of rotation and the amount of shift of the calibration substrate 20 calculated in step S3 and the amount of drift calculated in step S5.

When an acceleration as an evaluation target is left, for which the slip trigger stage operation has not been performed (step S8_No), the flow returns to step S5. The processes (steps S5 to S7) including the drift measurement, the slip trigger stage operation and the mark position measurement are performed for all accelerations as the evaluation targets.

After the slip trigger stage operation is performed for all accelerations as the evaluation targets (step S8_Yes), the calculating unit 33 calculates the amount of positional deviation (the amount of slip of the substrate) for each acceleration (step S9).

A case where 16 types of acceleration, accelerations A1 to A16 are sequentially set, and the slip trigger stage operation is performed will be described. After the slip trigger stage operation with the acceleration A1 is performed, the calculating unit 33 determines the amount of positional deviation F1 from the average of the difference between the design value and the measurement value at the positions of nine marks 28. The amount of positional deviation F1 corresponds to the slip of the substrate caused by the slip trigger stage operation with the acceleration A1.

After the slip trigger stage operation with the acceleration A2 is performed, the calculating unit 33 determines the amount of positional deviation F2 from the average of the difference between the design value and the measurement value at the positions of nine marks 28. The amount of positional deviation F2 is affected by slip of the substrate caused by the slip trigger stage operation with the acceleration A1 and slip of the substrate caused by the slip trigger stage operation with the acceleration A2. Thus, the amount of positional deviation (F2-F1) is determined by subtracting the amount of positional deviation F1 from the amount of positional deviation F2. The amount of positional deviation (F2-F1) corresponds the slip of the substrate caused by the slip trigger stage operation with the acceleration A2.

After the slip trigger stage operation with the acceleration A3 is performed, the calculating unit 33 determines the amount of positional deviation F3 from the average of the difference between the design value and the measurement value at the positions of nine marks 28. In the same manner as described above, the amount of positional deviation (F3-F2) is determined by subtracting the amount of positional deviation F2 from the amount of positional deviation F3. The amount of positional deviation (F3-F2) corresponds the slip of the substrate caused by the slip trigger stage operation with the acceleration A3.

Hereinafter, similarly, for each of the accelerations A4 to A16, the amount of positional deviation of the substrate caused by the slip trigger stage operation can be determined. Slip information indicating a relationship between acceleration and amount of positional deviation (amount of slip) of the substrate is stored in the storage device 35.

When the amount of positional deviation is less than or equal to a predetermined threshold value (value within a predetermined range), the calculating unit 33 determines that an acceleration corresponding to the performed slip trigger stage operation does not cause slip of the substrate 10 (in accuracy wise, the level of the slip causes no problem), and the acceleration is usable at the time of pattern writing. Note that the calibration substrate 20 and the substrate 10 for writing a product pattern are different in the centroid, material quality (such as a friction coefficient), or flatness, causing a slight difference in the amount of slip, but a high correlation is observed between the substrates.

When the substrate 10 is placed on the XY stage 52, and a writing process for a product pattern is performed, the acceleration setter 32 sets an acceleration determined to be usable at the time of pattern writing, and moves the XY stage 52. Consequently, a pattern can be written with high accuracy with a stage acceleration which causes no slip.

In this manner, according to the present embodiment, the slip trigger stage operation is performed with a plurality of stage accelerations, and mark scan of the calibration substrate 20 is performed for each of the accelerations to determine the amount of deviation of the mark position, thereby making it possible to determine the presence or absence of occurrence of slip of the substrate. In addition, drift measurement is performed before the slip trigger stage operation is performed, and a drift error is removed at the time of mark position calculation, thus the amount of slip of the substrate can be determined with high accuracy.

A technique may be adopted in which an evaluation pattern is written with a plurality of stage accelerations, and the presence or absence of occurrence of slip is determined from a result of the writing, but time is taken for the writing, development, etching and position measurement. In contrast, in the present embodiment, processes such as development and etching are unnecessary, thus the presence or absence of occurrence of slip of the substrate can be quickly determined.

In the present embodiment above, an example has been described in which the positions of nine marks 28 of the calibration substrate 20 are calculated, and the average of the amount of positional deviation is determined; however, the number of marks 28 whose positions are calculated is not limited to nine, and may be a number according to the position calculation accuracy.

In the present embodiment above, an example has been described in which 16 types of acceleration, accelerations A1 to A16 are sequentially set, and the slip trigger stage operation is performed; however, the slip trigger stage operation may be performed with the same acceleration multiple times, and the average of the amount of slip may be determined for each acceleration.

At least part of the control device 30 described in the above embodiments may be implemented in either hardware or software. When implemented in software, a program that realizes at least part of functions of the control device 30 may be stored on a recording medium such as a flexible disk or CD-ROM and read and executed by a computer. The recording medium is not limited to a removable recording medium such as a magnetic disk or optical disk, but may be a non-removable recording medium such as a hard disk device or memory.

The program that realizes at least part of the functions of the control device 30 may be distributed through a communication line (including wireless communications) such as the Internet. Further, the program may be encrypted, modulated, or compressed to be distributed through a wired line or wireless line such as the Internet or to be distributed by storing the program on a recording medium.

In the embodiment, the configuration in which a single beam is used has been described. However, the configuration in which a multi-beam is used may be adopted.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A slip evaluation method comprising:
placing a calibration substrate in which at least one mark is formed on a movable stage in a charged particle beam writing apparatus;
measuring a first position of the mark with the stage stopped;
performing a slip trigger stage operation at an acceleration to be evaluated;
measuring a second position of the mark with the stage stopped after the slip trigger stage operation is performed; and
calculating an amount of slip of the calibration substrate based on the first position and the second position.

2. The slip evaluation method according to claim 1,
wherein for each a plurality of accelerations to be evaluated, the slip trigger stage operation and measurement of the second position are performed to calculate the amount of slip of the calibration substrate.

3. The slip evaluation method according to claim 2,
wherein for each the plurality of accelerations to be evaluated, an amount of drift of the charged particle beam is measured, and the second position of the mark is determined in consideration of the amount of drift.

4. The slip evaluation method according to claim 1,
wherein with the stage stopped, a plurality of alignment marks formed in the calibration substrate are scanned by a charged particle beam, positions of the plurality of alignment marks are measured, and an amount of rotation and an amount of shift of the calibration substrate placed on the stage are calculated based on the positions of the plurality of alignment marks.

5. A charged particle beam writing method,
wherein in the slip evaluation method according to claim 2,
a writing target substrate is irradiated with a charged particle beam to write a pattern while the stage is being moved with an acceleration for which the amount of slip of the calibration substrate is in a predetermined range.
